(19) United States
(12) Patent Application Publication
(10) Pub. No.: US 2019/0385965 A1
(43) Pub. Date: Dec. 19, 2019

(54) SEMICONDUCTOR DEVICE AND SEMICONDUCTOR DEVICE MANUFACTURING METHOD

(71) Applicant: LAPIS SEMICONDUCTOR CO., LTD., Kanagawa (JP)

(72) Inventor: Taiichi OGUMI, Miyazaki (JP)

(21) Appl. No.: 16/552,270

(22) Filed: Aug. 27, 2019

Related U.S. Application Data
(62) Division of application No. 15/869,704, filed on Jan. 12, 2018, now abandoned.

(30) Foreign Application Priority Data
Jan. 16, 2017 (JP) 2017-005271

(51) Int. Cl. H01L 23/00

(52) U.S. Cl. CPC H01L 24/06; H01L 24/03; H01L 24/17; H01L 2224/0231; H01L 2224/02331; H01L 2924/01029; H01L 2924/01028

(57) ABSTRACT

A semiconductor device includes: a redistribution line provided on a main face of a first semiconductor chip; an insulating film covering a front face of the redistribution line, the insulating film including a first opening and a second opening that each partially expose the redistribution line; a first electrode provided on the insulating film, and is connected to the redistribution line at the first opening, the first electrode formed of the same material as the redistribution line; and a second electrode provided on the insulating film, and is connected to the redistribution line at the second opening, the second electrode formed of a material that differ from a material of the first electrode.

### CROSS-REFERENCE TO RELATED APPLICATION

This application is a divisional application of application Ser. No. 15/869,704 filed on Jan. 12, 2018, which claims priority under 35 USC 119 from Japanese Patent Application No. 2017-005271, filed on Jan. 16, 2017, the disclosure of which is incorporated by reference herein.

### BACKGROUND

### Technical Field

The present disclosure relates to a semiconductor device and a semiconductor device manufacturing method.

### Related Art

Wafer-level chip-size packaging (WL-CSP) is packaging technology for semiconductor devices in which redistribution wiring, electrode formation, resin encapsulation, and dicing are all performed in a wafer process. Multi-chip WL-CSP, in which plural semiconductor chips are stacked, is also known.

In Multi-chip WL-CSP, the planar size of the package is substantially the same as the planar size of any semiconductor chip packaged in the package, and the height of the package is substantially the same as the height of the stack of plural semiconductor chips packaged inside the package, thereby enabling package size to be reduced while still realizing high performance semiconductor devices. Moreover, since connections between the plural semiconductor chips are made using flip chip bonding, wire bonding is unnecessary, enabling improved performance due to, for example, suppressing communication lag between the semiconductor chips.

Japanese Patent Application Laid-Open (JP-A) No. 2008-218926 describes a semiconductor device manufacturing method that includes forming a columnar electrode on a semiconductor wafer, flip chip bonding a second semiconductor chip onto the semiconductor wafer, forming an encapsulation portion on the semiconductor wafer to encapsulate to cover the columnar electrode and the second semiconductor chip, and grinding the encapsulation portion and the second semiconductor chip so as to expose an upper face of the columnar electrode and an upper face of the second semiconductor chip.

In such a multi-chip WL-CSP, there may be issues with the reliability of the connection between a stacked first semiconductor chip and second semiconductor chip. Joining of the first semiconductor chip and the second semiconductor chip is, for example, performed by flip chip bonding the second semiconductor chip onto the first semiconductor chip using solder terminals containing SnAg. The solder terminals may, for example, be joined to redistribution lines formed on the front face of the first semiconductor chip during a redistribution wiring process or to electrodes. Generally, Cu is employed as the material for the redistribution lines and the electrodes formed on the front face of the first semiconductor chip in the redistribution wiring process. However, in such cases, there is a concern that the Cu configuring the redistribution lines and the electrodes may diffuse into the solder terminals such that the Cu at the solder joints of the redistribution lines or electrodes disappears, resulting in poor connections at the connections between the first semiconductor chips and the second semiconductor chips.

One example of a technique to suppress poor connections between semiconductor chips due to Cu diffusion into solder terminals is a technique in which the thickness of the redistribution lines or the electrode to be connected to a solder terminal is made thicker. Specifically, in this technique, a columnar electrode is formed at a joint between a first semiconductor chip and a second semiconductor chip. However, such a technique increases the thickness of the package, which is detrimental to the characteristic thinness of multi-chip WL-CSP.

### SUMMARY

The present disclosure provides a semiconductor device and a semiconductor device manufacturing method that may improve the reliability of connections between the semiconductor chips, without detriment to thinness in multi-chip WL-CSP.

A first aspect of the present disclosure is a semiconductor device including: a redistribution line provided on a main face of a first semiconductor chip; an insulating film covering a front face of the redistribution line, the insulating film including a first opening and a second opening that each partially expose the redistribution line; a first electrode provided on the insulating film, and is connected to the redistribution line at the first opening, the first electrode formed of the same material as the redistribution line; and a second electrode provided on the insulating film, and is connected to the redistribution line at the second opening, the second electrode formed of a material that differ from a material of the first electrode.

A second aspect of the present disclosure is a semiconductor device including: a redistribution line provided on a main face of a first semiconductor chip; an insulating film covering a front face of the redistribution line, the insulating film including a first opening and a second opening that each partially expose the redistribution line; a first electrode provided on the insulating film, and is connected to the redistribution line through a conductive film at the first opening; and a second electrode provided on the insulating film, and is connected to the redistribution line at the second opening, the second electrode formed of a material that differ from a material of the first electrode.

A third aspect of the present disclosure is a semiconductor device including: a first semiconductor chip; a first insulating film provided on a main face of the first semiconductor chip; a redistribution line provided on a front face of the first insulating film with a first conductive film interposed therebetween; a second insulating film covering a front face of the redistribution line, the second insulating film including a first opening and a second opening that each partially expose the redistribution line; a first electrode provided on the second insulating film, one end of the first electrode being connected to the redistribution line through a second conductive film at the first opening, and another end of the first electrode being connected to an external connection terminal; a second electrode provided on the second insulating film, and is connected to the redistribution line through the second conductive film at the second opening, the second electrode formed of a material that differ from a material of the first electrode; and a second semiconductor chip including, on a main face, a third electrode connected to the second electrode through solder.

A fourth aspect of the present disclosure is a semiconductor device manufacturing method including: forming a first insulating film on a main face of a first semiconductor chip; forming a redistribution line on a front face of the first insulating film with a first conductive film interposed therebetween; forming a second insulating film that covers a front face of the redistribution line, the second insulating film includes a first opening and a second opening that each partially expose the redistribution line; forming a first electrode on the second insulating film, the first electrode being connected to the redistribution line through a second conductive film at the first opening; forming a second electrode on the second insulating film, the second electrode being connected to the redistribution line through the second conductive film at the second opening and being formed of a material that differ from that of the first electrode; and connecting a third electrode provided on a main face of a second semiconductor chip to the second electrode.

According to the above aspects, the present disclosure may improve the reliability of connections between the semiconductor chips, without detriment to thinness in multi-chip WL-CSP.

### BRIEF DESCRIPTION OF THE DRAWINGS

Exemplary embodiments will be described in detail based on the following figures, wherein:

FIG. 1 is a cross-sectional view illustrating configuration of a semiconductor device according to an exemplary embodiment of the present disclosure;

FIG. 2 is an enlarged cross-sectional view illustrating configuration of part of a semiconductor device according to an exemplary embodiment of the present disclosure;

FIG. 3 is a plan view illustrating wiring configuration of a semiconductor device according to an exemplary embodiment of the present disclosure;

FIG. 4A to FIG. 4U are cross-sectional views illustrating manufacturing processes of a semiconductor device according to an exemplary embodiment of the present disclosure;

FIG. 5A is a plan view illustrating configuration of plating electrodes employed in plating processing to form redistribution lines according to an exemplary embodiment of the present disclosure;

FIG. 5B is a cross-sectional view taken along line A-A′ in FIG. 5A;

FIG. 6A is a plan view illustrating configuration of plating electrodes employed in plating processing to form chip interconnection electrodes and columnar electrodes according to an exemplary embodiment of the present disclosure;

FIG. 6B is a cross-sectional view taken along line B-B′ in FIG. 6A; and

FIG. 7 is a cross-sectional view illustrating configuration of a semiconductor device according to a comparative example.

### DETAILED DESCRIPTION

Explanation follows regarding an exemplary embodiment of the present disclosure, with reference to the drawings. Note that in the drawings, configuration elements and portions that are the same or equivalent in practice are allocated the same reference numerals.

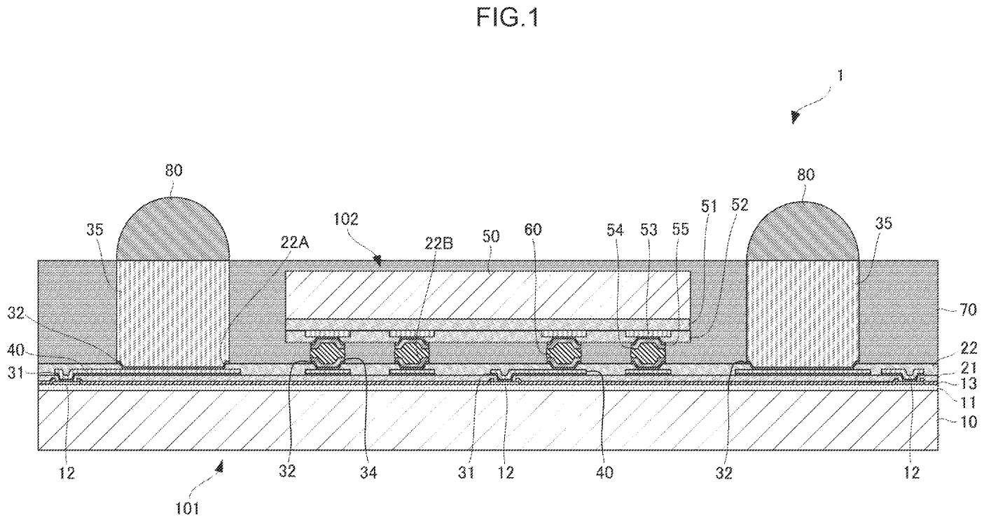

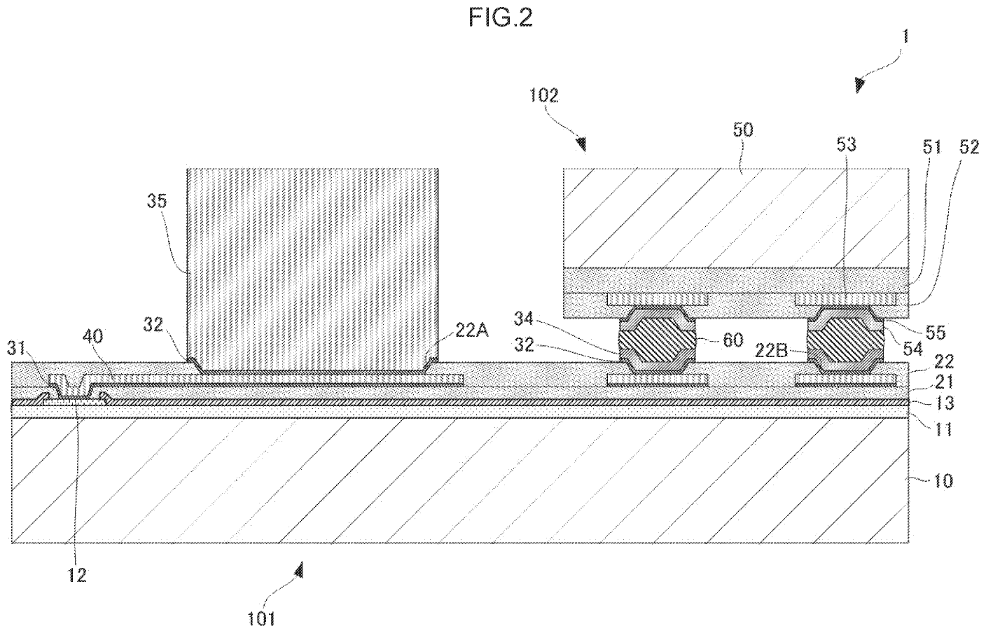

FIG. 1 is a cross-sectional view illustrating the overall configuration of a semiconductor device 1 according to an exemplary embodiment of the present disclosure. FIG. 2 is an enlarged cross-sectional view illustrating the configuration of part of the semiconductor device 1.

The semiconductor device 1 includes a first semiconductor chip 101, redistribution lines 40 provided on a main face of the first semiconductor chip 101, and a second semiconductor chip 102 connected to the first semiconductor chip 101 through the redistribution lines 40. The semiconductor device 1 further includes an encapsulation resin 70, columnar electrodes 35, and external connection terminals 80. The encapsulation resin 70 that covers the main face of the first semiconductor chip 101 such that the second semiconductor chip 102 is embedded within the encapsulation resin 70. The columnar electrodes 35 penetrate the encapsulation resin 70 so as to reach the redistribution lines 40. The external connection terminals 80 are provided to the tips of the columnar electrodes 35. Note that the encapsulation resin 70 and the external connection terminal 80 are omitted from illustration in FIG. 2.

The semiconductor device 1 is packaged using multi-chip WL-CSP. Namely, in the semiconductor device 1, the planar size of the package is substantially the same as the planar size of the first semiconductor chip 101, and the height of the package is substantially the same as the height of the stacked first semiconductor chip 101 and second semiconductor chip 102.

Circuit elements (not illustrated in the drawings) such as transistors, resistive elements, and capacitors are formed on a front face of a semiconductor substrate 10 configuring the first semiconductor chip 101. The front face of the semiconductor substrate 10 is covered by an inter-layer insulating film 11 configured by an insulator such as SiO₂. Chip electrodes 12 connected to the circuit elements formed on the semiconductor substrate 10, and a passivation film (protective film) 13 with openings that partially expose front faces of the chip electrodes 12, are both provided on a front face of the inter-layer insulating film 11.

A front face of the passivation film 13 is covered by a lower-layer insulating film 21 formed configured by photosensitive organic insulating material such as polyimide or polybenzoxazole (PBO). The lower-layer insulating film 21 is provided with openings that partially expose the front faces of the chip electrodes 12.

Each of the redistribution lines 40 is provided on a front face of the lower-layer insulating film 21 with a first under bump metallurgy (UBM) film 31 interposed therebetween. The first UBM film 31 is, for example, configured by a film stack including a Ti film and a Cu film. The Ti film functions as an adhesion layer to increase adhesion between the lower-layer insulating film 21 and the redistribution lines 40. The Cu film functions as a plating seed layer used to form the redistribution lines 40 in an electroplating method. Each of the redistribution lines 40 is, for example, configured by a conductor such as Cu. The redistribution lines 40 are respectively connected to the chip electrodes 12 through the first UBM film 31 at the openings in the lower-layer insulating film 21. The Cu film configuring the first UBM film 31 is incorporated into the Cu configuring the redistribution lines 40. A structure is thereby obtained in which a Ti film, functioning as an adhesion layer, is interposed between the lower-layer insulating film 21 and the redistribution lines 40.

Front faces of the lower-layer insulating film 21 and the redistribution lines 40 are covered by an upper-layer insulating film 22 configured by a photosensitive organic insulating material such as polyimide or PBO. The upper-layer insulating film 22 is provided with first openings 22A that partially expose the redistribution lines 40 at positions where the columnar electrodes 35 are formed, and with second openings 22B that partially expose the redistribution lines 40 at the positions where the chip interconnection electrodes 34 are formed.

The columnar electrodes 35 and the chip interconnection electrodes 34 are provided on the upper-layer insulating film 22. In plan view, the columnar electrodes 35 are formed in regions encompassing the first openings 22A in the upper-layer insulating film 22. The columnar electrodes 35 are respectively connected, through a second UBM film 32, to the portions of the redistribution lines 40 exposed through the first openings 22A. Cu, which is easy to work with, may preferably be employed as the material used for the columnar electrodes 35. The columnar electrodes 35 have, for example, cylindrical profiles.

In plan view, the chip interconnection electrodes 34 are formed in regions encompassing the second openings 22B in the upper-layer insulating film 22. The chip interconnection electrodes 34 are respectively connected, through the second UBM film 32, to the portions of the redistribution lines 40 exposed through the second openings 22B. The chip interconnection electrodes 34 are, for example, configured by a metal that does not diffuse into solder containing SnAg. Ni, for example, may preferably be employed as the material used for the chip interconnection electrodes 34. Namely, the chip interconnection electrodes 34 are configured from a material differing from that of the columnar electrodes 35.

The second UBM film 32 is provided between the redistribution lines 40 and the columnar electrodes 35, and between the redistribution lines 40 and the chip interconnection electrodes 34. Similarly to the first UBM film 31, the second UBM film 32 is configured by a film stack including a Ti film that functions as an adhesion layer, and a Cu film that functions as a plating seed layer. The Cu film configuring the second UBM film 32 is incorporated into the Cu configuring the columnar electrodes 35. A structure is thereby obtained in which the Ti film, functioning as an adhesion layer, is interposed between the columnar electrodes 35 and the redistribution lines 40. A structure is also obtained in which a film stack including a Ti film and a Cu film is interposed between the chip interconnection electrodes 34 and the redistribution lines 40.

The second semiconductor chip 102 is disposed on the first semiconductor chip 101 in a state in which a face on which circuit elements (not illustrated in the drawings) are formed opposes the first semiconductor chip 101. The second semiconductor chip 102 has a structure the same as, or similar to, that of the first semiconductor chip 101. Namely, a front face of a semiconductor substrate 50 configuring the second semiconductor chip 102 is provided with a lower-layer insulating film 51 configured by a photosensitive organic insulating material such as polyimide or PBO, and redistribution lines 53 are provided on the lower-layer insulating film 51. The redistribution lines 53 are connected, through chip electrodes (not illustrated in the drawings) that are provided on the front face of the semiconductor substrate 50, to circuit elements such as transistors (not illustrated in the drawings) that are provided on the front face of the semiconductor substrate 50.

Front faces of the lower-layer insulating film 51 and the redistribution lines 53 are covered by an upper-layer insulating film 52 configured by a photosensitive organic insulating material such as polyimide or PBO. The upper-layer insulating film 52 is provided with openings that partially expose the redistribution lines 53 at positions where the chip interconnection electrodes 54 are formed.

The chip interconnection electrodes 54 are provided on the upper-layer insulating film 52. In plan view, the chip interconnection electrodes 54 are formed in regions encompassing the openings in the upper-layer insulating film 52. The chip interconnection electrodes 54 are respectively connected to an exposed portion of the redistribution lines 53 through a UBM film 55. The chip interconnection electrodes 54 are, for example, configured by a metal that does not diffuse into solder containing SnAg. Ni, for example, may preferably be employed as the material used for the chip interconnection electrodes 54. The UBM film 55 is configured by a film stack including a Ti film that functions as an adhesion layer, and a Cu film that functions as a plating seed layer.

The chip interconnection electrodes 54 of the second semiconductor chip 102 are connected to the chip interconnection electrodes 34 of the first semiconductor chip 101 through solder terminals 60 configured by, for example, SnAg solder or the like. The circuit elements formed to the second semiconductor chip 102 are electrically connected to the circuit elements formed on the first semiconductor chip 101 or to the columnar electrodes 35 (external connection terminals 80) through the chip interconnection electrodes 34 and the redistribution lines 40 on the first semiconductor chip 101 side.

The encapsulation resin 70 is provided to the first semiconductor chip 101 on the side of a face joined to the second semiconductor chip 102. The second semiconductor chip 102 and the columnar electrodes 35 are embedded within the encapsulation resin 70. The tips of the columnar electrodes 35 are exposed from the front face of the encapsulation resin 70. The external connection terminals 80 configured by SnAg solder or the like are provided at the tips of the columnar electrodes 35. The external connection terminals 80 of the semiconductor device 1 are connected to a wiring substrate (not illustrated in the drawings) so as to mount the semiconductor device 1 on the wiring substrate.

Note that, in the example illustrated in FIG. 1, a face of the second semiconductor chip 102 on the opposite side to the face joined to the first semiconductor chip 101 (this face is referred to hereafter as the “back face”) is covered by the encapsulation resin 70. However, the back face of the second semiconductor chip 102 may be exposed from the encapsulation resin 70.

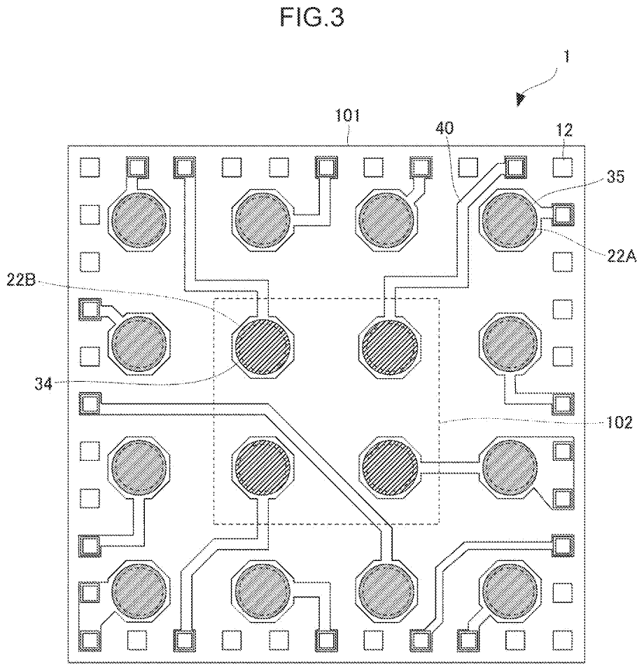

FIG. 3 is a plan view illustrating an example of a wiring configuration of the semiconductor device 1. As illustrated in FIG. 3, the chip electrodes 12 of the first semiconductor chip 101 are disposed along the edges of the rectangularly shaped first semiconductor chip 101. The redistribution lines 40 are connected to the chip electrodes 12, are drawn toward the inside in the plane direction of the first semiconductor chip 101, and are connected to the columnar electrodes 35 or to the chip interconnection electrodes 34. In the present exemplary embodiment, the chip interconnection electrodes 34 are disposed clustered around a central portion of the first semiconductor chip 101, and the columnar electrodes 35 are disposed so as to surround the outer periphery of the chip interconnection electrodes 34. The second semiconductor chip 102 is placed on the first semiconductor chip 101 at the central portion of the first semiconductor chip 101 where the chip interconnection electrodes 34 are disposed clustered together.

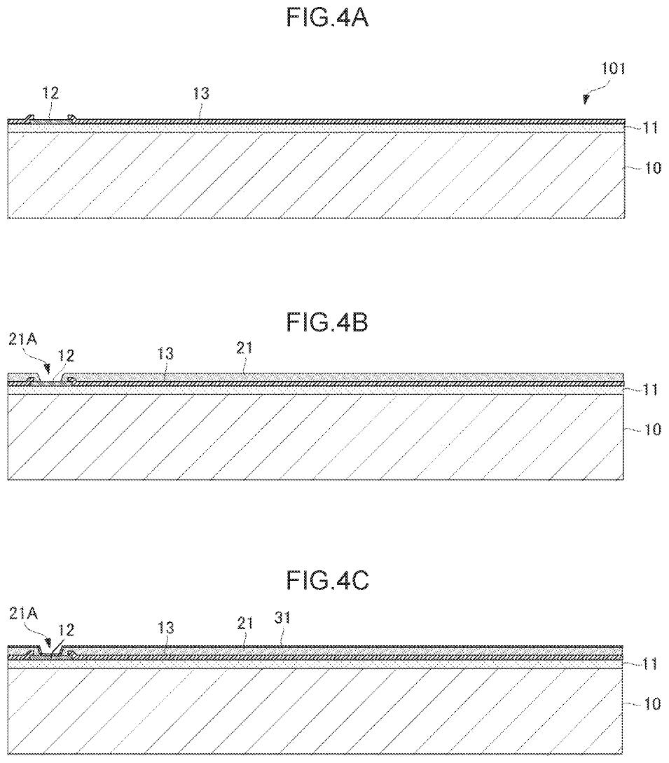

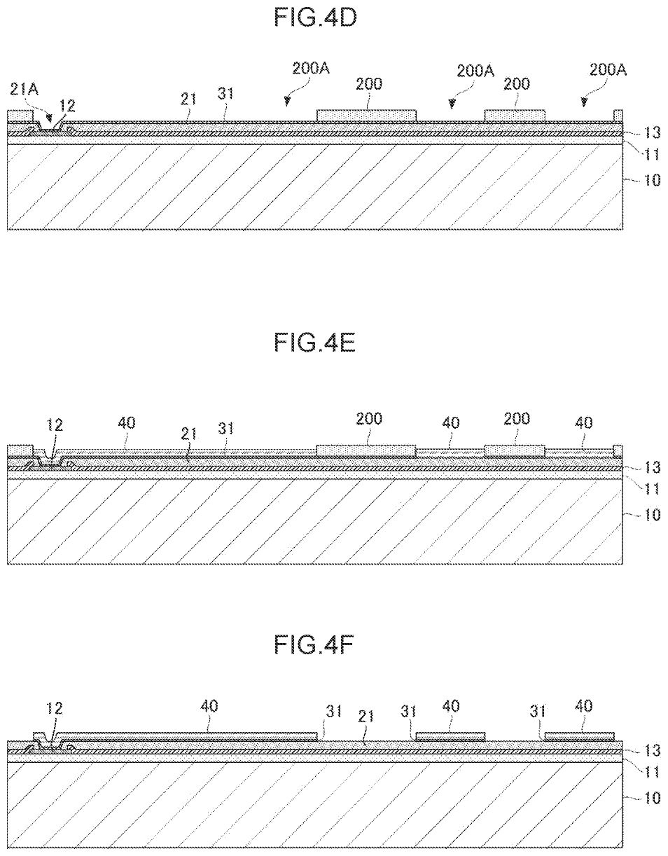

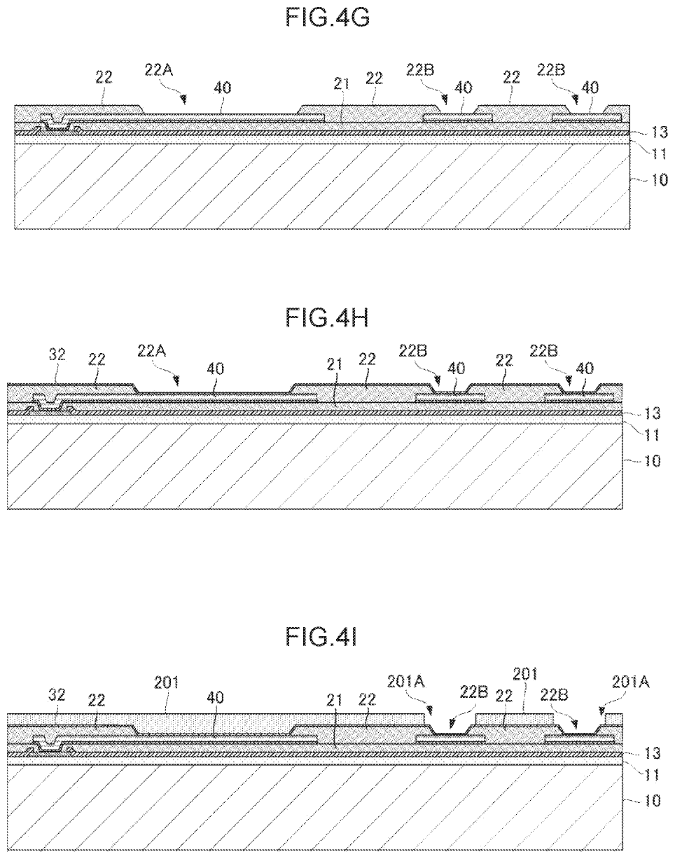

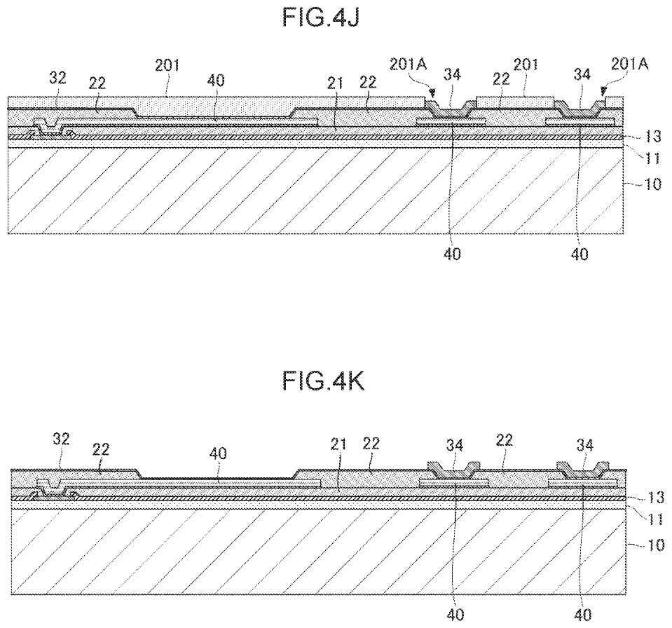

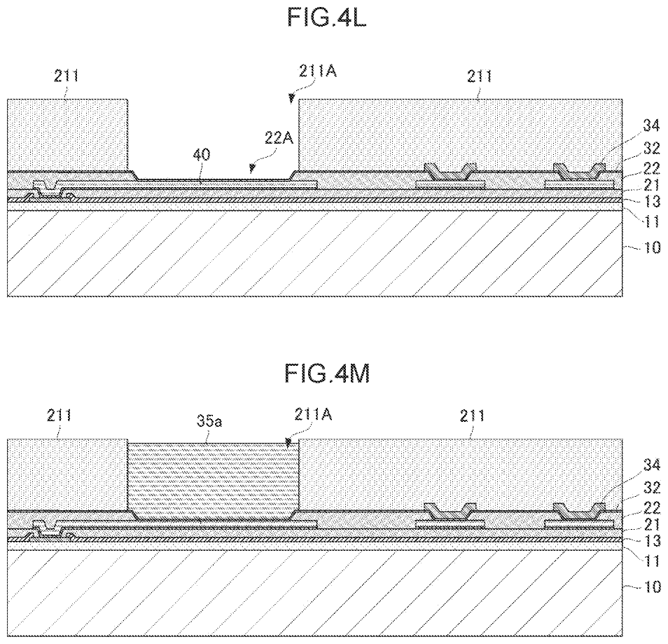

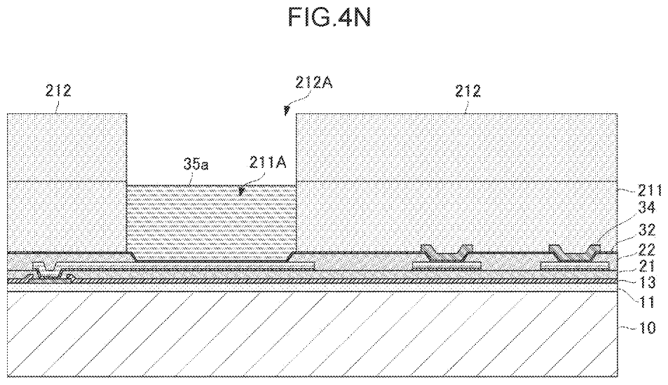

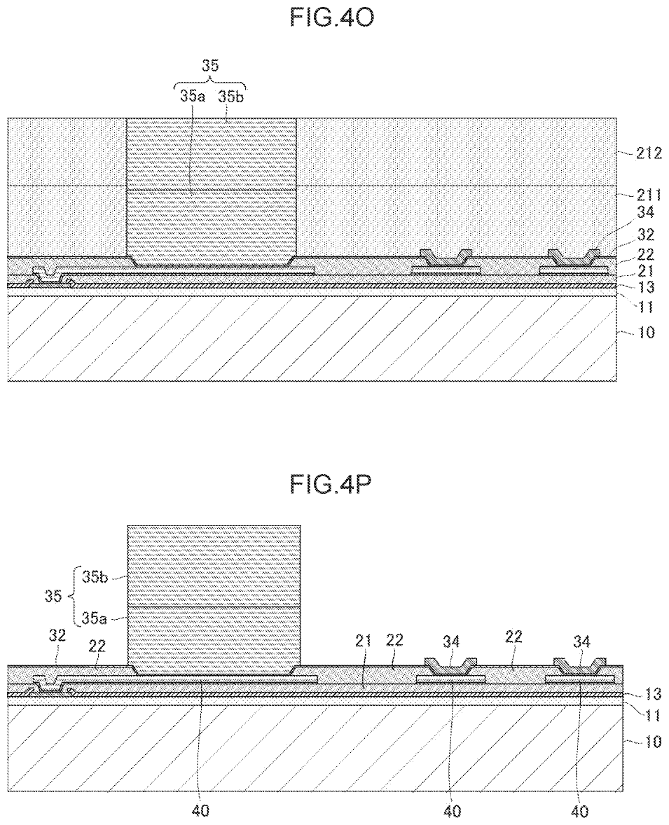

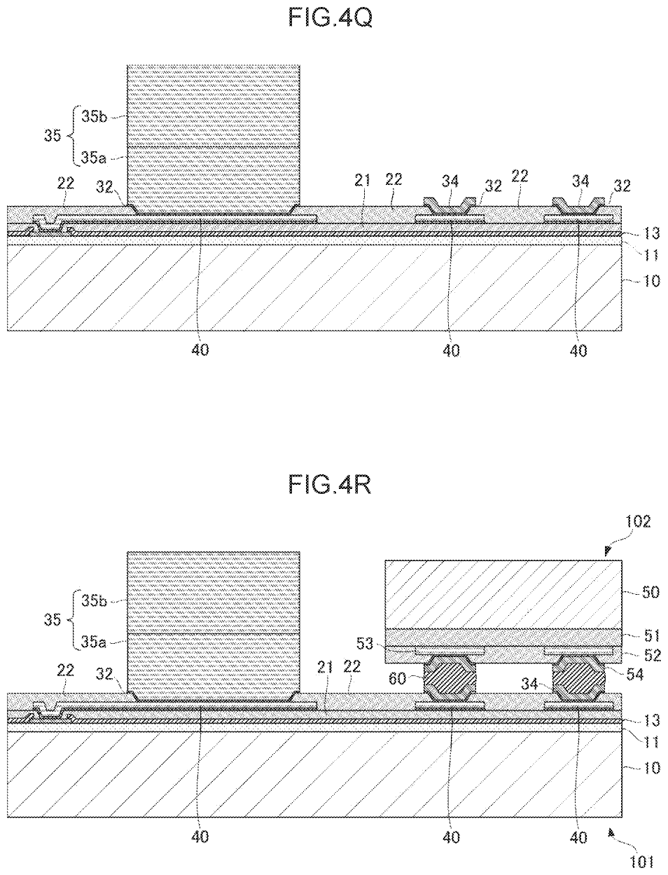

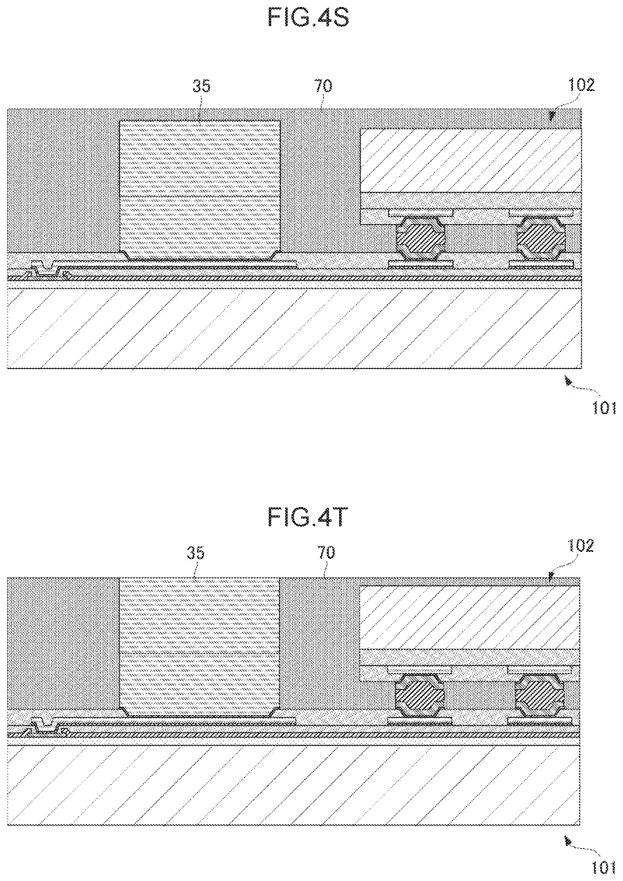

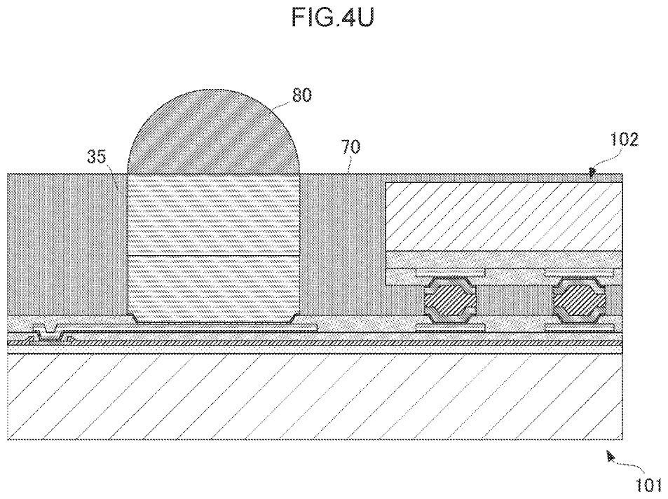

Explanation follows regarding a method of manufacturing the semiconductor device 1 according to the present exemplary embodiment, with reference to FIG. 4A to FIG. 4U. FIG. 4A to FIG. 4U are cross-sectional views illustrating manufacturing processes of the semiconductor device 1.

First, a semiconductor wafer on which the manufacturing processes of the first semiconductor chip 101 have been completed is prepared (FIG. 4A). The manufacturing processes of the first semiconductor chip 101 include forming circuit elements (not illustrated in the drawings) such as transistors on the semiconductor substrate 10; forming the inter-layer insulating film 11, configured by an insulator such as SiO₂, on the front face of the semiconductor substrate 10; forming the chip electrodes 12 on the front face of the inter-layer insulating film 11; and forming the passivation film (protective film) 13 on the front face of the inter-layer insulating film 11 such that the chip electrode 12 is partially exposed.

Next, for example, a spin coating method is employed to coat the front face of the first semiconductor chip 101 with a photosensitive organic insulating material such as polyimide or PBO, thereby forming the lower-layer insulating film 21 that covers the front faces of the passivation film 13 and the chip electrodes 12. Then, exposure and developing processing is performed on the lower-layer insulating film 21 to form the openings 21A partially exposing the front faces of the chip electrodes 12 in the lower-layer insulating film 21. The lower-layer insulating film 21 is then cured using thermal processing (FIG. 4B).

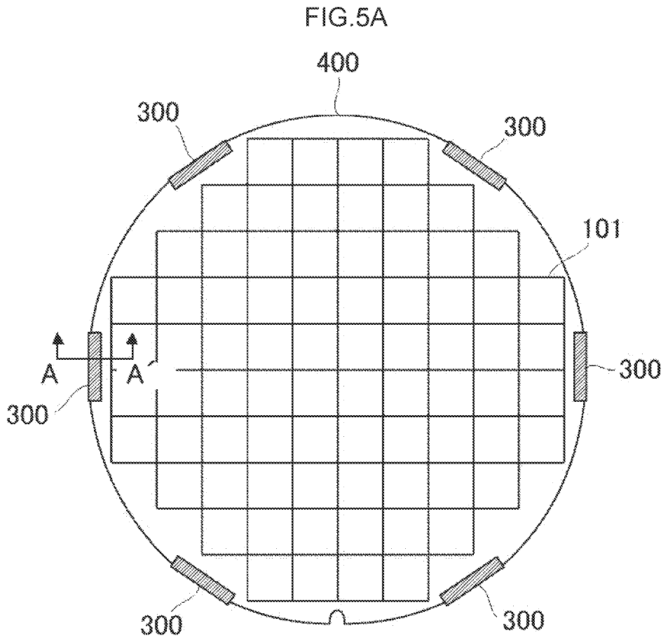

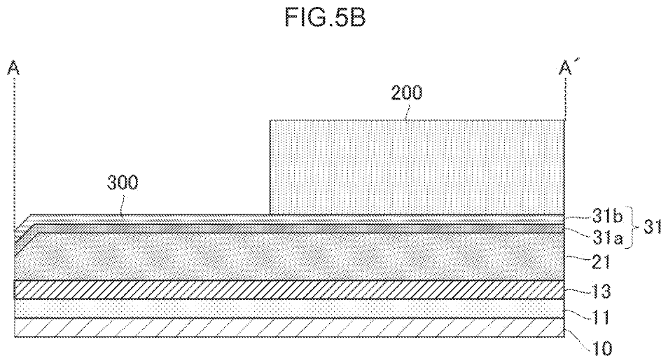

Next, the first UBM film 31 is formed covering the front face of the lower-layer insulating film 21 and the front face of the chip electrodes 12 exposed through the openings 21A (FIG. 4C). The first UBM film 31 is, for example, formed by successively forming a Ti film and a Cu film using a sputtering method. The Ti film functions as an adhesion layer to increase adhesion between the lower-layer insulating film 21 and the redistribution lines 40. The Cu film functions as a plating seed layer used to form the redistribution lines 40 in an electroplating method. Plating electrodes 300 (see FIG. 5A and FIG. 5B) that are connected to the first UBM film 31 at an outer peripheral portion of the semiconductor wafer are also formed in this process. The plating electrodes 300 are, for example, formed by successively forming a Ti film and a Cu film, similarly to the first UBM film 31. The plating electrodes 300 are employed during formation of the redistribution lines 40 in an electroplating method of a subsequent process.

Next, known photolithography technology is employed to form a resist mask 200 having openings 200A corresponding to the pattern of the redistribution lines 40 on the front face of the first UBM film 31 (FIG. 4D). The resist mask 200 is formed by coating the first UBM film 31 with a photosensitive resin and performing exposure and developing processing on the photosensitive resin.

Next, an electroplating method is employed to form the redistribution lines 40 on the front face of the first UBM film 31 (see FIG. 4E). Specifically, the front face of the semiconductor substrate 10 is immersed in a plating solution, and current is supplied to the plating electrodes 300 (see FIG. 5A and FIG. 5B) connected to the first UBM film 31. Metal is thereby deposited on the exposed portions of the first UBM film 31 (plating seed layer) to form the redistribution lines 40 on the first UBM film 31. Cu, for example, may be employed as the material for the redistribution lines 40. In such cases, the plating seed layer configuring the first UBM film 31 is incorporated into the Cu of the redistribution lines 40. A structure is thereby obtained in which a Ti film, functioning as an adhesion layer, is interposed between the redistribution lines 40 and the lower-layer insulating film 21.

Note that FIG. 5A is a plan view illustrating configuration of the plating electrodes 300 employed in the plating processing to form the redistribution lines 40. FIG. 5B is a cross-sectional view taken along line A-A′ in FIG. 5A. As illustrated in FIG. 5A, the plating electrodes 300 are provided at plural locations of an outer peripheral portion of a semiconductor wafer 400 formed with plural of the first semiconductor chips 101. Each of the plural plating electrodes 300 is connected to the first UBM film 31. The first UBM 31 and the plating electrodes 300 are each configured by a film stack of a Ti film 31a and a Cu film 31b. The Ti film 31a functions as an adhesion layer and the Cu film 31b functions as a plating seed layer. The redistribution lines 40 are formed on the first UBM film 31 by supplying current to the plating electrodes 300 in a state in which the front face of the semiconductor substrate 10 is immersed in a plating solution.

After forming the redistribution lines 40, the resist mask 200 is removed using a known ashing process or an organic solvent or the like. Unwanted portions of the first UBM film 31 that were covered by the resist mask 200 are then removed using the redistribution lines 40 as a mask (FIG. 4F). This also removes the plating electrodes 300 employed in the plating processing to form the redistribution lines 40.

Next, for example, a spin coating method is employed to coat the front face of the structure formed by the above processing with a photosensitive organic insulating material such as polyimide or PBO, thereby forming the upper-layer insulating film 22 covering the front faces of the lower-layer insulating film 21 and the redistribution lines 40. Then, the upper-layer insulating film 22 is subjected to exposure and developing processing to form, in the upper-layer insulating film 22, the first openings 22A and the second openings 22B partially exposing the front face of the redistribution lines 40. In plan view, the first openings 22A are formed in regions encompassed by the regions for forming the columnar electrodes 35. In plan view, the second openings 22B are formed in regions encompassed by the regions for forming the chip interconnection electrodes 34. The upper-layer insulating film 22 is then cured using thermal processing (FIG. 4G).

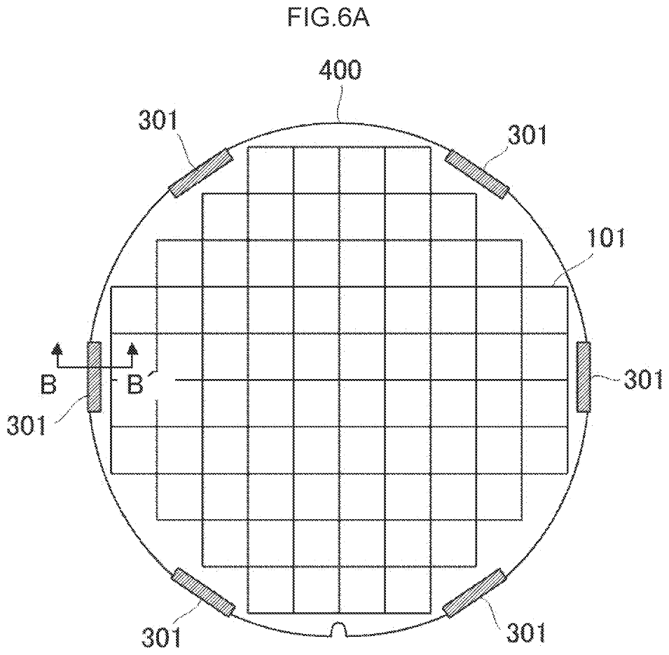

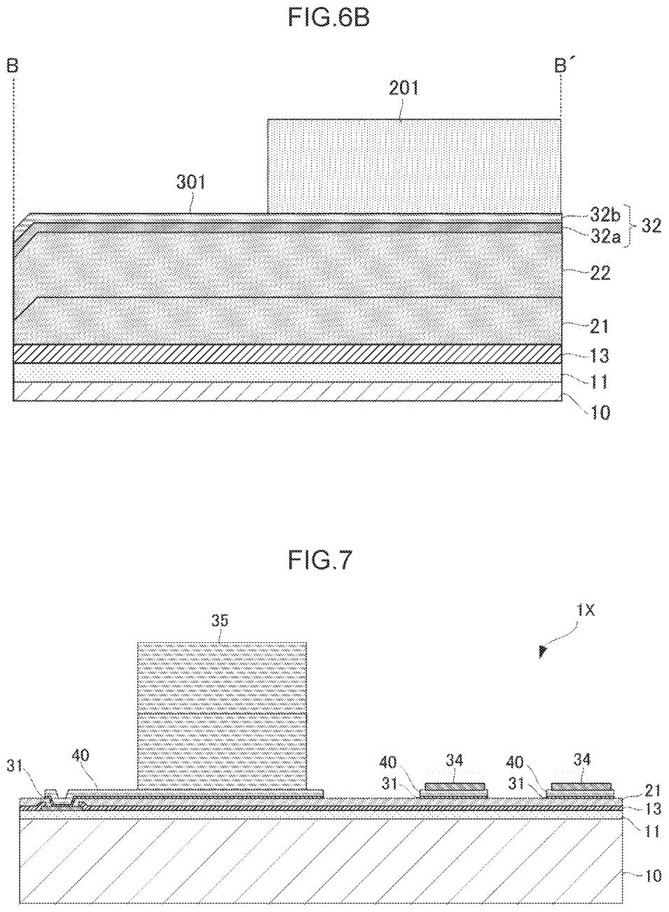

Next, the second UBM film 32 is formed covering the front face of the upper-layer insulating film 22 and the front face of the redistribution lines 40 exposed through the first openings 22A and the second openings 22B (FIG. 4H). The second UBM film 32 is, for example, formed by successively forming a Ti film and a Cu film using a sputtering method. The Ti film functions as an adhesion layer to increase adhesion between the upper-layer insulating film 22 and the columnar electrodes 35, and between the upper-layer insulating film 22 and the chip interconnection electrodes 34. The Cu film functions as a plating seed layer used to form the columnar electrodes 35 and the chip interconnection electrodes 34 in an electroplating method. In the present process, plating electrodes 301 (see FIG. 6A and FIG. 6B) connected to the second UBM film 32 are also formed at an outer peripheral portion of the semiconductor wafer. The plating electrodes 301 are, for example, formed by successively forming a Ti film and a Cu film, similarly to the second UBM film 32. The plating electrodes 301 are employed during formation of the chip interconnection electrodes 34 and the columnar electrodes 35 in an electroplating method of a subsequent process.

Next, known photolithography technology is employed to form a resist mask 201 having openings 201A in regions for forming the chip interconnection electrodes 34 (FIG. 4I) on the front face of the second UBM film 32. The resist mask 201 is formed by coating the second UBM film 32 with a photosensitive resin and performing exposure and developing processing on the photosensitive resin. The openings 201A in the resist mask 201 encompass the second openings 22B of the upper-layer insulating film 22, and thereby expose the second openings 22B.

Next, an electroplating method is employed to form the chip interconnection electrodes 34 on the front face of the second UBM film 32 exposed through the openings 201A in the resist mask 201 (FIG. 4J). Specifically, the front face of the semiconductor substrate 10 is immersed in a plating solution, and current is supplied to the plating electrodes 301 (see FIG. 6A and FIG. 6B) connected to the second UBM film 32. Metal is thereby deposited on the exposed portions of the second UBM film 32 (plating seed layer) to form the chip interconnection electrodes 34 on the second UBM film 32. The chip interconnection electrodes 34 are connected to the redistribution lines 40 through the second UBM film 32. Ni, which does not diffuse into solder containing SnAg, may preferably be employed as the material used for the chip interconnection electrodes 34. In such cases, a structure of stacked Ti, Cu, and Ni is obtained at portions where the front face of the redistribution lines 40 is exposed through the second openings.

Next, the resist mask 201 is removed using a known ashing process or an organic solvent or the like (FIG. 4K).

Next, a first dry film layer 211 is affixed to the front face of the structure formed by the above processing, so as to cover the front faces of the second UBM film 32 and the chip interconnection electrodes 34. The first dry film layer 211 is a photosensitive resist member in film form, and is, for example, affixed using an affixing machine. Exposure and developing processing is then performed on the first dry film layer 211 to form openings 211A at regions for forming the columnar electrodes 35. The openings 211A in the first dry film layer 211 encompass the first openings 22A in the upper-layer insulating film 22, and thereby expose the first openings 22A (FIG. 4L).

Next, an electroplating method is employed to form the columnar electrodes 35 on the front face of the second UBM film 32 exposed through the openings 211A in the first dry film layer 211 (FIG. 4M). Specifically, the front face of the semiconductor substrate 10 is immersed in a plating solution, and current is supplied to the plating electrodes 301 (see FIG. 6A and FIG. 6B) connected to the second UBM film 32. Metal is thereby deposited on the exposed portions of the second UBM film 32 (plating seed layer) to form lower-layer portions 35a of the columnar electrodes 35 on the second UBM film 32. Note that the lower-layer portions 35a are preferably formed such that a height position of the upper faces of the lower-layer portions 35a of the columnar electrodes 35 is lower than the height position of the upper face of the first dry film layer 211. Cu, which is easy to work with, may preferably be employed as the material used for the columnar electrodes 35. In such cases, the Cu film functioning as a plating seed layer configuring the second UBM film 32 is incorporated into the Cu configuring the columnar electrodes 35. A structure is thereby obtained in which a Ti film, functioning as an adhesion layer, is interposed between the columnar electrodes 35 and the redistribution lines 40.

Next, a second dry film layer 212 is affixed to the front face of the first dry film layer 211. Similarly to the first dry film layer 211, the second dry film layer 212 is a photosensitive resist member in film form, and is, for example, affixed using an affixing machine. Exposure and developing processing is then performed on the second dry film layer 212 to form openings 212A at regions for forming the columnar electrodes 35. Namely, the openings 212A in the second dry film layer 212 are in communication with the openings 211A in the first dry film layer 211, and the lower-layer portions 35a of the columnar electrodes 35 are exposed through openings 212A in the second dry film layer 212 (FIG. 4N).

Next, an electroplating method is employed to form upper-layer portions 35b of the columnar electrodes 35 on the front faces of the lower-layer portions 35a of the columnar electrodes 35 exposed through the openings 212A in the second dry film layer 212 (FIG. 4O). Specifically, the front face of the semiconductor substrate 10 is immersed in a plating solution, and current is supplied to the plating electrodes 301 (see FIG. 6A and FIG. 6B) connected to the second UBM film 32. Metal is thereby deposited on the front faces of the lower-layer portions 35a of the columnar electrodes 35 to form the upper-layer portions 35b of the columnar electrodes 35 on the front faces of the lower-layer portions 35a of the columnar electrodes 35. Note that the upper-layer portions 35b are preferably formed such that a height position of the upper faces of the upper-layer portions 35b of the columnar electrodes 35 is higher than the height position of the upper face of the second dry film layer 212.

FIG. 6A is a plan view illustrating configuration of the plating electrodes 301 employed in the plating processing to form the chip interconnection electrodes 34 and the columnar electrodes 35. FIG. 6B is a cross-sectional view taken along line B-B′ in FIG. 6A. As illustrated in FIG. 6A, similarly to the plating electrodes 300 employed in the plating processing to form the redistribution lines 40, the plating electrodes 301 are provided at plural locations around the outer peripheral portion of the semiconductor wafer 400 on which the plural first semiconductor chips 101 are formed. Each of the plural plating electrodes 301 is connected to the second UBM film 32. The second UBM film 32 and the plating electrodes 301 are each configured by a film stack of a Ti film 32a and a Cu film 32b. The Ti film 32a functions as an adhesion layer and the Cu film 32b functions as a plating seed layer. The chip interconnection electrodes 34 are formed on the second UBM film 32 by supplying current to the plating electrodes 301 in a state in which the front face of the semiconductor substrate 10 is immersed in a plating solution. Then, the columnar electrodes 35 are formed on the second UBM film 32 by supplying current to the plating electrodes 301 in a state in which the front face of the semiconductor substrate 10 is immersed in a different plating solution.

After forming the columnar electrodes 35, an organic stripping solution or the like is employed to remove the first dry film layer 211 and the second dry film layer 212 (FIG. 4P).

Next, unwanted portions of the second UBM film 32 that had been covered by the first dry film layer 211 are removed using the columnar electrodes 35 and the chip interconnection electrodes 34 as a mask (FIG. 4Q). This also removes the plating electrodes 301 employed in the plating processing to form the chip interconnection electrodes 34 and the columnar electrodes 35.

Next, the second semiconductor chip 102 is placed on the first semiconductor chip 101 (FIG. 4R). The second semiconductor chip 102 is configured including the semiconductor substrate 50, the lower-layer insulating film 51, the redistribution lines 53, the upper-layer insulating film 52, and the chip interconnection electrodes 54. The first semiconductor chip 101 and the second semiconductor chip 102 are, for example, joined using the solder terminals 60 containing SnAg. Specifically, the solder terminals 60 are formed on the chip interconnection electrodes 54 on the second semiconductor chip 102 side, and then, reflow processing is performed in a state in which the solder terminals 60 are in contact with the chip interconnection electrodes 34 on the first semiconductor chip 101 side. The chip interconnection electrodes 34 and 54 are configured using Ni, which does not diffuse into the solder terminals 60, enabling the reliability of the connections between the first semiconductor chip 101 and the second semiconductor chip 102 to be improved compared to cases in which the chip interconnection electrodes 34 and 54 contain Cu, which is the material configuring the columnar electrodes 35. Note that although in the present exemplary embodiment explanation has been given regarding an example in which the chip interconnection electrodes 34 on the first semiconductor chip 101 side are configured using Ni, the chip interconnection electrodes 34 may also be configured by a film stack in which Ni and SnAg have been stacked.

Next, for example, a screen printing method is employed to coat the front face of the structure formed by the above processing with the encapsulation resin 70. The columnar electrodes 35 and the second semiconductor chip 102 are embedded within the encapsulation resin 70. The encapsulation resin 70 is then cured using thermal processing (FIG. 4S).

Next, a grinder is employed to grind the front face of the encapsulation resin 70 and expose the tips of the columnar electrodes 35. The back face of the first semiconductor chip 101 (the face on the opposite side to the side on which the second semiconductor chip 102 has been placed) may be ground as necessary to make the semiconductor device 1 thinner (FIG. 4T). Moreover, although in the present exemplary embodiment the back face of the second semiconductor chip 102 (the face on the opposite side to the face joined to the first semiconductor chip 101) is covered by the encapsulation resin 70, the back face of the second semiconductor chip 102 may be exposed from the encapsulation resin 70.

Next, the external connection terminals 80 are formed on the tips of the columnar electrodes 35 exposed from the encapsulation resin 70 (FIG. 4U). The external connection terminals 80 are, for example, formed by performing reflow processing after placing solder balls containing SnAg, for example, on the tips of the columnar electrodes 35. The external connection terminals 80 may also be formed by forming a conductive paste containing SnAg, for example, on the tips of the columnar electrodes 35 using screen printing, and then performing reflow processing.

In the semiconductor device 1 and the manufacturing method thereof according to the exemplary embodiment of the present disclosure, the columnar electrodes 35 are easy to work with, since the columnar electrodes 35 are configured including Cu. The chip interconnection electrodes 34 and 54 connected to the SnAg-containing solder terminals 60 do not contain Cu, which is liable to diffuse into the solder terminals 60, but as their main material do contain Ni, which does not diffuse into the solder terminals 60. Accordingly, the risk of the chip interconnection electrodes 34 and 54 disappearing after a long period of use can be eliminated. Namely, the semiconductor device 1 according to the present exemplary embodiment may improve the reliability of connections between the semiconductor chips, without detriment to thinness.

As described above, in the semiconductor device 1 according to the present exemplary embodiment, the columnar electrodes 35 and the chip interconnection electrodes 34 are configured by mutually different materials. Thus, it is necessary to perform plating processing to form the columnar electrodes 35 separately from plating processing to form the chip interconnection electrodes 34. Namely, in cases in which the columnar electrodes 35 and the chip interconnection electrodes 34 are configured by mutually different materials, the number of plating processes is increased, in compared to cases in which the columnar electrodes 35 and the chip interconnection electrodes 34 are configured by the same material.

FIG. 7 is a cross-sectional view illustrating configuration of a semiconductor device 1X according to a comparative example. The semiconductor device 1X according to the comparative example is not provided with the upper-layer insulating film 22 provided to the semiconductor device 1 according to the exemplary embodiment of the present disclosure, and in the semiconductor device 1X the columnar electrodes 35 and the chip interconnection electrodes 34 are provided on the redistribution lines 40. In the semiconductor device 1X according to the comparative example, similarly to in the semiconductor device 1 according to the exemplary embodiment of the present disclosure, the columnar electrodes 35 are configured from Cu, and the chip interconnection electrodes 34 are configured from Ni.

In the semiconductor device 1X according to the comparative example, in plating processing to form the redistribution lines 40, both plating processing to form the chip interconnection electrodes 34 and plating processing to form the columnar electrodes 35 are performed using plating electrodes connected to the UBM film 31 provided in the layer under the redistribution lines 40.

Note that in electroplating processing, each time plating processing is performed, the plating electrodes are etched by plating solution. Accordingly, if the number of plating processes increase, there is a concern that the plating electrodes may be removed such that plating processing cannot be suitably performed.

Moreover, in cases in which the plating electrodes are, for example, configured by a film stack of a Ti film and a Cu film, the Cu film is etched by the plating solution, while the Ti film is not etched and therefore remains. It is therefore conceivable that plating electrode functionality might be maintained by the remaining Ti film. However, the Ti film has a higher resistance value than the Cu film, such that were plating processing to be performed using plating electrodes configured only by Ti films, the growth rate of the metal deposited by the plating processing would be slower than in cases in which plating processing is performed using plating electrodes configured by a film stack of a Ti film and a Cu film.

Moreover, in cases in which plating electrodes configured by only a Ti film and plating electrodes configured by a film stack of a Ti film and a Cu film are both present over the semiconductor wafer, the growth rate of the metal deposited by the plating processing becomes uneven, resulting in concerns of uneven thickness of the redistribution lines 40 over the semiconductor wafer, uneven thickness of the chip interconnection electrodes 34, and uneven height of the columnar electrodes 35 over the semiconductor wafer.

Were the thickness of redistribution lines 40 and the thickness of the chip interconnection electrodes 34 to become uneven across the semiconductor wafer, this would result in variation in the resistance values of the redistribution lines 40 and the chip interconnection electrodes 34 between different semiconductor devices. Moreover, since it is necessary to completely cover the columnar electrodes 35 with the encapsulation resin 70, were the heights of the columnar electrodes 35 to become uneven over the semiconductor wafer, it would be necessary to increase the thickness of the encapsulation resin 70. Increasing the thickness of the encapsulation resin 70 would increase warping in the semiconductor wafer. Increased warping of the semiconductor wafer would make it more difficult to fix the semiconductor wafer to a stage in a encapsulation resin 70 grinding process performed after forming the encapsulation resin 70, a semiconductor substrate 10 grinding process, and a semiconductor wafer dicing (singularization) process, giving rise to concerns of being unable to perform these processes.

In the semiconductor device 1X according to the comparative example, plating processing to form the redistribution lines 40, plating processing to form the chip interconnection electrodes 34, and plating processing to form the columnar electrodes 35 are all performed using the plating electrodes connected to the UBM film 31 provided in the layer under the redistribution lines 40. Therefore, there is a high risk of excessive etching of the plating electrodes, and a high risk of the above issues arising.

However, in the semiconductor device 1 according to the exemplary embodiment of the present disclosure, the insulating film provided on the first semiconductor chip 101 is configured by two layers (namely, the lower-layer insulating film 21 and the upper-layer insulating film 22), and the plating electrodes 300 connected to the first UBM film 31 formed on the lower-layer insulating film 21 are employed in the plating processing to form the redistribution lines 40, while the plating electrodes 301 connected to the second UBM film 32 formed on the upper-layer insulating film 22 are employed in the plating processing to form the chip interconnection electrodes 34 and the columnar electrodes 35. Thus, since the plating electrodes employed in the plating processing to form the redistribution lines 40 and the plating electrodes employed in the plating processing to form the chip interconnection electrodes 34 and the columnar electrodes 35 differs, the risk of excessive etching of the plating electrodes may be suppressed, and the risk of the above issues arising may be suppressed.

In this manner, in the semiconductor device 1 and the manufacturing method thereof according to the exemplary embodiment of the present disclosure, since the columnar electrodes 35 and the chip interconnection electrodes 34 are configured by mutually different materials, although the number of plating processes is increased compared to cases in which the columnar electrodes 35 and the chip interconnection electrodes 34 are configured by the same material, the risk of excessive etching of the plating electrodes accompanying an increase in the number of plating processes may be suppressed, and issues arising when excessive etching of the plating electrodes occurs may be avoided.

Note that the first semiconductor chip 101 is an example of a first semiconductor chip of the present disclosure. The second semiconductor chip 102 is an example of a second semiconductor chip of the present disclosure. The redistribution lines 40 are examples of a redistribution line of the present disclosure. The lower-layer insulating film 21 is an example of a first insulating film of the present disclosure. The upper-layer insulating film 22 is an example of an insulating film or a second insulating film of the present disclosure. The columnar electrodes 35 are examples of a first electrode of the present disclosure. The chip interconnection electrodes 34 are examples of a second electrode of the present disclosure. The chip interconnection electrodes 54 are examples of a third electrode of the present disclosure. The first UBM film 31 is an example of a first conductive film of the present disclosure. The second UBM film 32 is an example of a conductive film or a second conductive film of the present disclosure. The plating electrodes 300 are examples of a first plating electrode of the present disclosure. The plating electrodes 301 are examples of a second plating electrode of the present disclosure.

What is claimed is:

1. A semiconductor device manufacturing method comprising:
forming a first insulating film on a main face of a first semiconductor chip;
forming a redistribution line on a front face of the first insulating film with a first conductive film interposed therebetween;
forming a second insulating film that covers a front face of the redistribution line, the second insulating film includes a first opening and a second opening that each partially expose the redistribution line;
forming a first electrode on the second insulating film, the first electrode being connected to the redistribution line through a second conductive film at the first opening;
forming a second electrode on the second insulating film, the second electrode being connected to the redistribution line through the second conductive film at the second opening and being formed of a material that differ from that of the first electrode; and
connecting a third electrode provided on a main face of a second semiconductor chip to the second electrode.

2. The manufacturing method of claim 1, wherein:
the redistribution line is formed by electroplating processing using a first plating electrode that is connected to the first conductive film; and
the first electrode and the second electrode are formed by electroplating processing using a second plating electrode that is connected to the second conductive film.

3. The manufacturing method of claim 1, wherein:
the first electrode contains copper; and
the second electrode contains nickel.

4. The manufacturing method of claim 1, wherein the first electrode is formed by performing electroplating processing a plurality of times.

5. The manufacturing method of claim 1, further comprising:
forming an encapsulation resin to embed the first electrode and the second semiconductor chip within the encapsulation resin;
grinding a front face of the encapsulation resin to expose a front face of the first electrode; and
forming an external connection terminal on the exposed front face of the first electrode.
